(19) United States
(12) Patent Application Publication
(10) Pub. No.: US 2006/0055024 A1
(43) Pub. Date: Mar. 16, 2006

(54) Adapted leaded integrated circuit module

(75) Inventor: James Douglass Wehrly JR., Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group, L.P.

(21) Appl. No.: 10/940,074

(22) Filed: Sep. 14, 2004

(51) Int. Cl. H01L 23/48; H01L 23/34

(52) U.S. Cl. 257/693; 257/723

(57) ABSTRACT

An interposer is provided having an array of surface mount pads along the upper side and an array of BGA (ball grid array) contacts on the lower side. A module of one or more leaded packaged ICs (integrated circuits) is mounted to the array of surface mount pads. The one or more leaded packaged integrated circuits are thereby adapted for connection to a BGA footprint. Various alternative embodiments for stacking the leaded packaged ICs, controlling thermal performance, and interconnecting with the interposer are disclosed.

### FIELD

The present invention relates to interconnects among integrated circuits, and especially adapters for mounting integrated circuit modules.

### BACKGROUND

Leaded chip packages typically have an IC chip encapsulated in a plastic body. A lead frame typically penetrates the plastic body to enable connection of the IC chip to external leads arranged along a lateral side of the plastic body. The external leads electrically connect the IC chip to an operating environment, such as, for example, a circuit board. Typical CSP (chip-scale) chip packages also have an IC chip encapsulated in a plastic body. A CSP body is, however, typically smaller than a leaded body. A CSP body typically has an array of BGA (ball grid array) contacts along a planar lower side that connect the IC chip to an operating environment. CSP packaging technology is newer than most leaded packaging technology and accounts for a large percentage of packaged ICs sold in the market. Leaded packaging technology still has a significant share of the market, especially for lower cost, commodity ICs and ICs that require comparatively fewer input/output connections, such as, for example, memory ICs.

A variety of techniques are used to interconnect packaged ICs into high density stacked modules. Some techniques require special packages, while other techniques employ conventional packages. In some techniques, flexible conductors are used to selectively interconnect packaged integrated circuits. Staktek Group L.P. has developed numerous systems for aggregating packaged ICs in both leaded and CSP packages into space saving topologies.

Memory expansion is one of the many fields in which stacked module solutions provide space saving advantages. For example, the well-known DIMM (Dual In-line Memory Module) board is frequently populated with stacked modules built by Staktek Group L.P. of Austin, Tex. Such modules add capacity to the board without adding sockets. A memory expansion board such as, for example, a DIMM, provides plural sites, or footprints, for memory IC placement arranged along one or both major surfaces of the board. Many memory expansion boards or other circuit boards are designed with footprints for expensive CSP packages having high density memory chips. Such arrangements provide a circuit board with a high memory density.

An equivalent high density may be achieved for a circuit board by employing lower cost leaded packaged ICs in high density stacked modules. The design of the circuit board or other constraints such as the density of connections may not allow, however, the use of a leaded footprint to mount the stacked module of leaded packaged ICs.

What is needed, therefore, are methods and structures for stacking circuits in thermally efficient, reliable structures that can be made at reasonable cost with commonly available and readily managed materials. What is also needed are methods to connect ICs in leaded packages to footprints of CSP packages.

### SUMMARY

An interposer is provided having an array of surface mount pads along the upper side and an array of BGA (ball grid array) contacts along the lower side. A module of one or more leaded packaged ICs (integrated circuits) is mounted to the array of surface mount pads. The one or more leaded packaged integrated circuits are thereby adapted for connection to a BGA footprint.

The BGA contacts may, in other embodiments, be pin grid array contacts, solder bumps, metalized bumps, or other high density or low profile contact arrangements. The BGA contacts are preferably connected to the surface mount pads on the interposer with vertical vias and horizontal traces. The interposer may have more than one metal layer for electrical connectivity and/or heat distribution. Thermal adhesive or thermal grease may be employed between the interposer and the adjacent leaded packaged IC. Also, thermal adhesive or thermal grease, or heat spreaders may be employed between adjacent pairs of stacked ICs.

Multiple leaded packaged ICs may be stacked. Some embodiments may have only one leaded packaged IC. In preferred embodiments, ICs in a stack are interconnected with flexible circuit connectors. In other embodiments, contact members or carrier structures or other leaded stacking techniques may be employed.

### BRIEF DESCRIPTION OF THE DRAWINGS

FIG. 1 depicts a cross-sectional view of a circuit module according to a preferred embodiment of the present invention.

FIG. 2A depicts a cross-sectional view of a portion of one embodiment of an interposer.

FIG. 2B depicts a cross-sectional view of a portion of another embodiment of an interposer.

FIG. 3 depicts an enlarged cross-sectional view of one preferred embodiment of a module according to the present invention.

FIG. 4 depicts an exemplar layout of a flexible circuit connector according to one embodiment of the present invention.

FIG. 5 depicts a cross-sectional view of an alternative preferred embodiment having contact members.

FIG. 6 depicts a cross-sectional view of another alternative embodiment having a carrier structure.

### DETAILED DESCRIPTION OF PREFERRED EMBODIMENTS

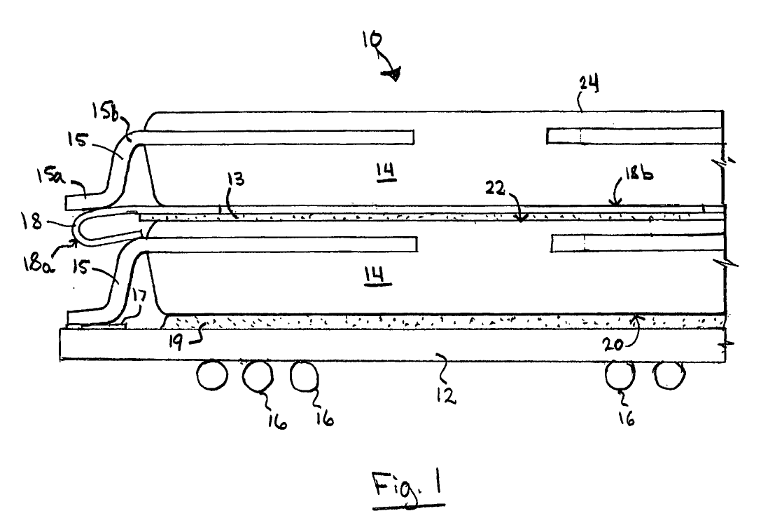

FIG. 1 depicts a cross-sectional view of a circuit module 10 according to a preferred embodiment of the present invention. Interposer 12 adapts ICs 14 for connection to an operating environment through BGA contacts 16. Lower IC 14 has leads 15 (“leads”, “external leads”) attached to surface mount pads 17. Preferably, ICs 14 are interconnected with flexible circuit connector 18. Adhesive 13 attaches flexible circuit connector 18 to top surface 22 of the lower depicted IC 14. Bottom surface 20 of the lower depicted IC 14 is thermally coupled to interposer 12 by thermal adhesive 19.

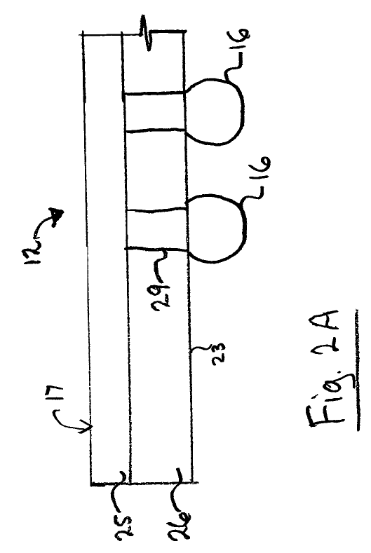

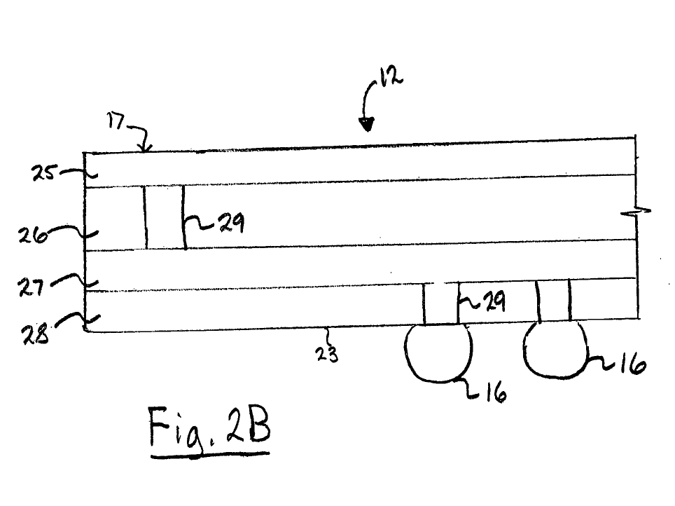

Interposer 12 (“interposer”, “transition interposer”) may be made of a flexible circuit or a PCB (printed circuit board) or other type of substrate. Interposer 12 may be made of more than one piece. Preferably, interposer 12 has two conductive layers which are further described with reference to FIG. 2. BGA contacts 16 (ball grid array contacts) on interposer 12 may be solder balls or other types of electrical contacts such as, for example, PGA (pin grid array), solder bumps, metalized bumps, copper pads, or low profile contacts comprising a built-up conductive pad or conductive pad with solder. Interposer 12 has surface mount pads 17 for connection to ICs 14. While the depicted surface mount pad 17 is shown above the surface of interposer 12, this is not limiting and surface mount pads 17 may be flush or below the surface. Preferably, surface mount pads are copper or a copper alloy and are etched in a conductive layer of interposer 12. Etching and other techniques for producing patterned conductive layers are known in the art. An insulative layer may be provided over portions of the upper of interposer 12.

In this embodiment, thermal adhesive 19 attaches the lower depicted IC 14 to interposer 12. In other embodiments, thermal adhesive 19 may instead be other material, such as, for example, thermal grease, or a heat spreader. Such material need not be adhesive, but adhesion is preferred. Some embodiments may have some portions of thermal grease, which typically conducts heat better than an adhesive, and other portions of a thermal adhesive. Other embodiments may have a gap or may have lower surface 20 flush with interposer 12. Heat conductive material is preferred.

In this embodiment, module 10 includes first and second ICs 14 stacked atop each other. Each IC 14 typically includes a package 24 that protectively encapsulates an internal semiconductor die. Typically, external leads 15 extend out from the lateral sides of package 24. Only one side of module 10 is shown to simplify the depiction. Although two ICs 14 are shown, this is not limiting and a module 10 may be constructed with one, two, three, or more ICs 14. Some preferred embodiments employ 4-high stacks of ICs. In preferred embodiments, ICs 14 are TSOP (thin small-outline packaged) devices with leads extending from a pair of oppositely-facing peripheral sides. However, the invention can be used with any commercially available packaged devices and other devices including, for example, TSOPs, custom thin, and high lead count packaged integrated circuit devices. The leaded ICs may have leads on more than two sides. Leads 15 are preferably aligned for stacking. Body 24 of the lower IC 14 is depicted attached to flexible circuit connector 18 with adhesive 13. Other embodiments may instead have a thermally conductive film or thermal grease, or may have no attachment means under the body of lower IC 14. Further, the depicted upper IC 14 may also be attached or thermally coupled to flexible circuit connector 18 with adhesive, thermal adhesive, thermally conductive film, or thermal grease.

FIG. 2A depicts a cross-sectional view of a portion of one embodiment of an interposer 12. In this embodiment, interposer 12 has conductive layer 25 and substrate layer 26. Conductive layer 25 may be constructed of any suitable material such as, for example, copper, alloy 110, or other metals and alloys. Conductive layer 25 is preferably constructed by deposition and etching to form surface mount pads 17 and various conductive traces.

Substrate layer 26 may be constructed from materials such as, for example, FR4 (flame retardant type 4) epoxy laminate, or PTFE (poly-tetra-fluoro-ethylene), or polyimide. Vias such as exemplar vias 29 pass through conductive layer 26 to electrically and thermally connect conductive layer 25 to BGA contacts 16. Vias 29 are preferably copper-clad or filled vias. Construction of such vias is known in the art. In other embodiments, BGA contacts 16 may be attached to conductive layer 25 through windows formed in substrate layer 26. Other embodiments may be constructed with other methods for connecting BGA contacts to interposers. BGA contacts 16 are preferably arrayed in grid patterns along bottom surface 23 of interposer 12. Other patterns, such as, for example, peripheral patterns, may be used. In a preferred embodiment, memory TSOPs are attached to interposer 12 and their leads 15 electrically connected to BGA contacts 16 in a manner devised to match the BGA ballout pattern for a desired standard memory IC.

FIG. 2B depicts a cross-sectional view of a portion of another embodiment of an interposer 12. In this embodiment, interposer 12 is a circuit board having conductive layers 25 and 27, and substrate layers 26 and 28. Construction of circuit boards from such materials is well known in the art. Conductive layers 25 and 27 may express ground or power planes and may act as a thermal distribution layer.

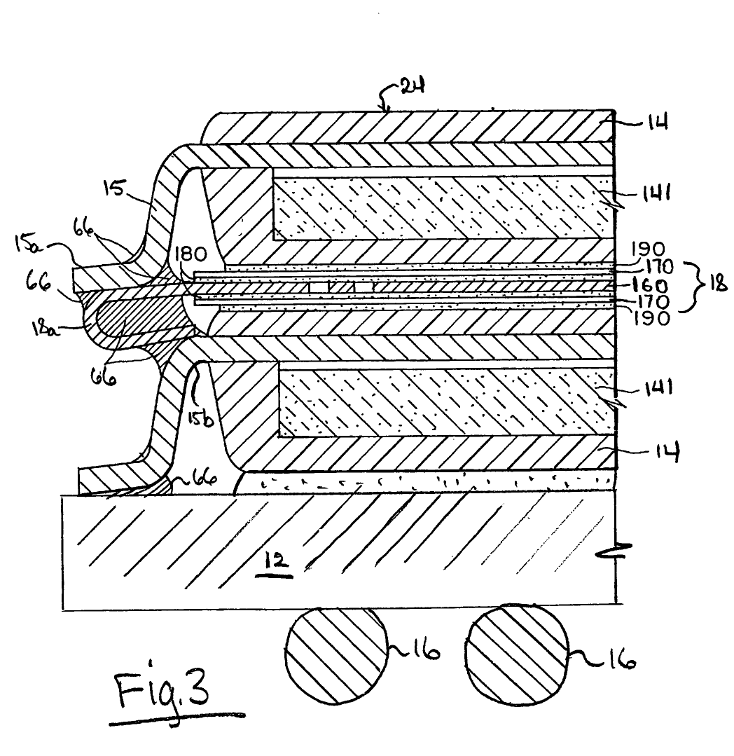

FIG. 3 depicts an enlarged cross-sectional view of one preferred embodiment of a module 10 of the present invention. In this embodiment, ICs 14 are connected with flexible circuit connector 18. While only one flexible circuit connector is shown, more than one may be used to interconnect ICs 14. Distal ends 18a of flexible circuit connector 18 are bent into ‘J’s for interconnecting flexible circuit connector 18 to leads 15 on both sides of ICs 14, preferably with the assistance of solder (or another suitable bonding material). Other embodiments may have such structures on more than two sides of an IC 14. A distal end 18a may constitute, however, any suitable structure for connecting aligned external leads to one another. Such an end could include, but is not limited to J-shaped tabs, C-shaped tabs, bifurcated ends, and gull-wing tab ends. Distal ends 18a connect the ‘foot’ 15a of upper leads 15 to the ‘knee’ 15b of lower leads 15. Other embodiments may have other configurations with connections to different portions of leads 15, especially lower leads 15.

In this embodiment, flexible circuit connector 18 comprises conductor assembly 160 sandwiched between first and second insulator (electrical) layers 170. Flexible circuit connector 150 also includes adhesive element 180 between insulator layers 170 for adherence to conductor assembly 160. Upper and lower packaged ICs 14 are mounted against the first (upper) and second (lower) insulator layers 170 of flexible circuit connector 150 through a thermally-conductive (e.g., thin film) adhesive 190 in order to thermally connect and structurally secure flexible connector 18 and packaged ICs 14 in a stack configuration. Finally, solder 66 electrically and structurally connects adjacent external leads 15 to one another through conductor assembly 160. It should be recognized that the phrase “mounted against” does not mean that the insulator layers 170 are necessarily in direct physical contact with the IC bodies 24. As in the depicted embodiment, they may be separated by adhesive 190 or other suitable material. It simply means that the flexible circuit connector 150 is mounted—either directly or indirectly—between adjacent IC bodies 24. This concept of “mounted against” also applies with respect to the insulator layers 170 being mounted against the conductor assembly 160.

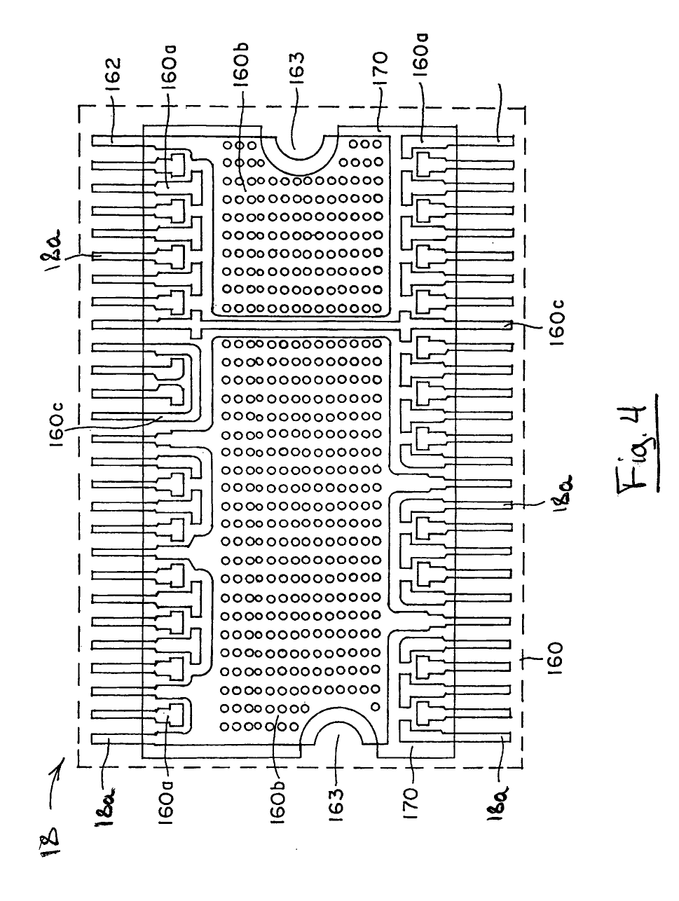

FIG. 4 depicts one preferred embodiment of a flexible circuit conductor 18. Depicted are stacked packaged ICs 14 mounted to interposer 12. This depiction includes an embodiment of semiconductor die 141 inside packaged ICs 14, not shown in other Figures to clarify the drawings. Conductor assembly 160 of flexible circuit connector 18 comprises a plurality of discrete conductors including singular conductors 160a, ground plane and thermal element conductors 160b, and jumper conductors 160c. Each discrete conductor includes at least one distal end 162 for electrically connecting to one another aligned external leads 15 from first and second ICs 14. Aligned external leads in general are vertically aligned leads from adjacent IC devices that are in a stacked configuration. Aligned leads normally (but not always) correspond to like, adjacent leads (or pins) from like, adjacently stacked devices. In the depicted embodiments, the overall group of discrete conductors 160a, 160b, 160c define a generally planar conductor assembly 160. Flexible circuit connector 18 may also include offset notches 163 (which in the depicted embodiment are part of the ground conductor portions) for cooperating with automated manufacturing equipment (not shown) to ensure that the flexible circuit connector 18 is properly oriented during manufacturing.

Discrete conductors 160a, 160b, 160c are generally thin, trace-like members that are electrically and thermally conductive. They in connection with insulator layers 170 may be formed using conventional flex circuit methods. Accordingly, flexible circuit connectors 18 of the present invention may be derived from commercially available flexible circuit sources. In addition, the flexible circuit may either be single-sided (single insulative layer 170) or double-sided (first and second insulative layers 170).

A singular conductor 160a is a discrete conductor with one distal end for simply connecting a pair of aligned external leads 15. A ground plane conductor 160b is a discrete conductor that (either alone or in connection with other ground plane conductors) has a relatively large surface area, as compared to other individual discrete conductors, for functioning (e.g., signal return path) as a ground plane. In addition, a ground plane conductor has one or more distal ends 162 for electrical and thermal connection to external leads 15 that are to be grounded. A jumper conductor 160c is a discrete conductor with two or more distal ends for connecting two or more external leads of IC 14 to one another and with their corresponding aligned leads from an adjacent package. A ground plane and thermal element 160b may be segmented in order for a jumper conductor 160c to connect external leads 15 that extend from different peripheral sides of an IC 14. Alternatively, such a “jumped” connection could be made by using a multi-layered flexible circuit with overlapping and/or crossing (but not contacting) conductors.

A discrete conductor may be formed from any suitable material such as ½ hard copper 110 alloy. Electrical insulator layer(s) 170 may also be formed from any suitable flex circuit material, which when in contact with conductors sufficiently electrically isolates the discrete conductors from one another. In addition, electrical insulator layers 170 preferably have favorable heat transfer properties. Such a material would include, for example, a thin or a thermally conductive polyimide.

Ground plane and thermal element 160b, apart from the other discrete conductors, generally reside in the center portion of the flexible circuit connector 18 approximately corresponding in size to the size of ICs 14. This ground plane and thermal element 160b improves the heat transfer capability of flex circuit connector 18. This enables the flex circuit connector 18 to more effectively conduct thermal energy between the multiple stacked ICs 14 so that each IC 14 in the module 10 benefits from the heat dissipation capacity of the whole module 10.

In one preferred embodiment, flexible circuit connector 18 is built according to the design found in U.S. Pat. No. 6,572,387 to Burns et al, issued Jun. 3, 2003, which is assigned to Staktek Group, L.P. In other embodiments, ICs 14 may be stacked with other methods such as, for example, contacts members found in U.S. Pat. No. 6,462,408 to Wehrly, Jr., issued Oct. 8, 2002, which is also assigned to Staktek Group, L.P.

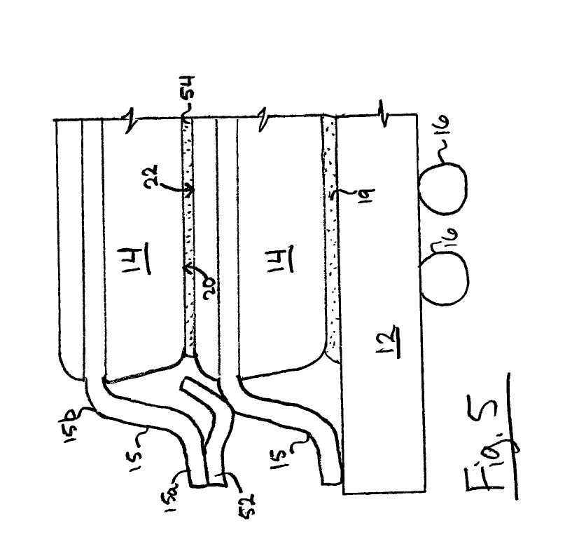

FIG. 5 depicts a cross-sectional view of an alternative preferred embodiment having contact members 52. In this embodiment, ICs 14 are interconnected with contact member 52 between leads 15. Contact member 52 is preferably soldered to foot 15a of upper IC 14 and soldered to knee 15b of lower IC 14. However, this is merely an example and other arrangements may be used contacting other parts of leads 15. The depicted packaged ICs 14 are attached to each other with adhesive 54, which is preferably thermally conductive adhesive such as thin film adhesive. Also, thermal grease may be used between ICs 14.

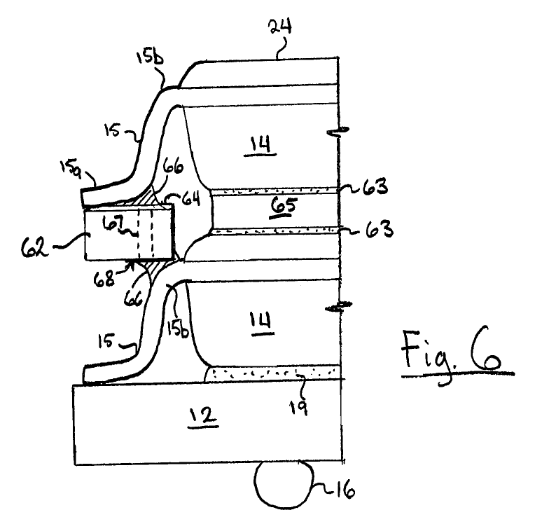

FIG. 6 depicts a cross-sectional view of another alternative embodiment having carrier structures 62. The depicted lead 15 of upper IC 14 is soldered with solder 66 to pad 64 on carrier structure 62. Connected to pad 64 is trace 68 which traverses the lateral side of carrier structure 62 and is soldered to knee 15b of lower lead 15. In other embodiments, vias or other conductive structures may connect pad 64 to a conductive trace or pad placed for soldering to lower lead 15. An exemplar via 67 is shown in outlined in the cross section of carrier structure 62. Vias may provide better thermal conductivity than traces and thereby enhance the thermal distribution qualities of module 10.

Carrier structure 62, in a preferred embodiments, is constructed with PCB (printed circuit board) material or other carrier material. Preferably, carrier structure 62 extends along all the leads on one lateral side of an IC 14. In a preferred method of making carrier structure 62, a larger circuit board is routed, drilled, and divided into multiple carrier structures 62. Metalization along the lateral sides of carrier structure 62, such as trace 68, may be added after division. Preferred designs of carrier structure 62 are found in U.S. Pat. No. 6,608,763 to Burns et al., issued Aug. 19, 2003, which is assigned to Staktek Group, L.P.

In this embodiment, bodies 24 of ICs 14 have in between them heat spreader 65, which may be attached to ICs 14 with thermal adhesive 63. Thermal adhesive 63 may also be thermal grease. Other embodiments may not have a heat spreader 65.

Although the present invention has been described in detail, it will be apparent to those skilled in the art that many embodiments taking a variety of specific forms and reflecting changes, substitutions and alterations can be made without departing from the spirit and scope of the invention. The described embodiments illustrate the scope of the claims but do not restrict the scope of the claims.

1. A high density circuit module comprising:
first and second leaded packaged integrated circuits each having a plurality of leads, the first and second leaded packaged integrated circuits being selectively interconnected and arranged in a stack with one above the other, the first leaded packaged integrated circuit being lowermost in the stack;
an interposer having an array of BGA contacts and an array of surface mount pads selectively connected to the array of BGA contacts;
the first leaded packaged integrated circuit being attached to the array of surface mount pads.

2. The high density circuit module of claim 1 in which the first and second leaded packaged integrated circuits are selectively interconnected with a flexible circuit, the flexible circuit having a first set of electrical contacts and a second set of electrical contacts, the first set of electrical contacts connecting to leads of the first leaded packaged integrated circuit and the second set of electrical contacts connecting to leads of the second leaded packaged integrated circuit.

3. The high density circuit module of claim 1 in which the first and second leaded packaged integrated circuits are selectively interconnected with contact members.

4. The high density circuit module of claim 1 in which the first and second leaded packaged integrated circuits are selectively interconnected with metalized PCBs.

5. A method of interconnecting integrated circuits including the steps:
providing an interposer having a top side and a bottom side;
forming an array of surface mount contacts along the top side of the interposer;
forming a grid of contacts along the bottom side of the interposer;
providing two or more leaded integrated circuits for stacking;
designating one of the two or more leaded integrated circuits as a lower leaded integrated circuit;
mounting the lower leaded integrated circuit to the array of surface mount contacts;
stacking the two or more leaded integrated circuits and electrically interconnecting selected leads of the two or more leaded integrated circuits to form an integrated circuit stack.

6. The method of claim 5 further including the step of attaching a body of the lower leaded integrated circuit to the interposer with thermally conductive adhesive.

7. The method of claim 5 further including the step placing thermal grease between the lower leaded integrated circuit and the interposer.

8. The method of claim 5 further in which the interposer has a thermal distribution layer.

9. The method of claim 5 in which the step of stacking the two or more leaded integrated circuits includes positioning a flexible interposer between respective pairs of the two or more leaded integrated circuits.

10. The method of claim 5 in which the step of stacking the two or more leaded integrated circuits includes positioning contact members between respective pairs of leads of the two or more leaded integrated circuits.

11. A high density circuit module including a transition interposer, the transition interposer having a top side, a bottom side, a plurality of surface mount pads arrayed along the top side, a plurality of BGA balls arrayed along the bottom side, and a plurality of conductive paths connecting selected ones of the surface mount pads to selected ones of the BGA balls.

12. The high density circuit module of claim 11 further including a stack of leaded integrated circuits, the stack having a bottom integrated circuit package, the bottom integrated circuit package mounted to the plurality of surface mount pads of the transition interposer.

13. The high density circuit module of claim 11 in which the stack of leaded integrated circuits is a stack of TSOPs.

14. The high density circuit module of claim 11 in which the transition interposer has a thermal distribution layer.

15. The high density circuit module of claim 11 in which the stack of leaded integrated circuits is a stack of TSOPs, the stack of TSOPs being interconnected with contact members.

16. The high density circuit module of claim 11 in which the stack of leaded integrated circuits is a stack of TSOPs, the stack of TSOPs being interconnected with one or more flexible circuit connectors.

17. The high density circuit module of claim 11 in which the transition interposer is a flexible circuit.

18. The high density circuit module of claim 11 in which the transition interposer is a printed circuit board.

19. The high density circuit module of claim 11 in which the bottom integrated circuit package is attached to the transition interposer with thermally conductive adhesive.

20. The high density circuit module of claim 11 further including thermal grease between the bottom integrated circuit package and the transition interposer.
